(19) United States
(12) Patent Application Publication
(10) Pub. No.: US 2008/0023062 A1
(43) Pub. Date: Jan. 31, 2008

(54) Holographic imaging passive tracking solar energy filter, concentrator and converter with PV cell cooling means

(76) Inventor: Arlen Barksdale, Encinitas, CA (US)

Correspondence Address: GARY L. EASTMAN, EASTMAN & ASSOCIATES, 707 BROADWAY STREET, SUITE 1800, SAN DIEGO, CA, 92101, US

(21) Appl. No.: 11/029,902

(22) Filed: Jan. 4, 2005

(51) Int. Cl. H01L 31/055; H01L 31/058

(52) U.S. Cl. 136/248; 136/246

(57) ABSTRACT

An invention to passively track the sun for the purposes of collecting, filtering and concentrating sunlight simultaneously and variously onto a photovoltaic cell, a heat collection device, and a thermally activated cooling device for the PV cell in order to efficiently and economically produce electrical power. The invention comprises a holographic light gathering element that also splits the light frequencies and focuses to two or more points or lines. The light frequency is split such that the UV wavelength of interest for PV cell operation is split from all the other wavelengths and focused on the PV cell or light conducting media that will direct the UV to the PV cell location. The other wavelengths of the solar spectrum are focused on a different location that can be simply a “throw-away” of this excess heat or it can be usably focused on a bulb or pipe which collects the heat.

### RELATED APPLICATIONS

This application claims the benefit of the filing date of co-pending provisional application Ser. No. 60/533,935.

### FIELD OF THE INVENTION

This invention relates generally to the field of apparatus for a passive tracking solar energy filter, concentrator and converter with a PV cell cooling means. Moreover it pertains specifically to such apparatus for converting sunlight into electrical energy.

### BACKGROUND OF THE INVENTION

In view of the limitations now present in the prior art, the present invention provides a new and useful invention to passively track the sun for the purposes of collecting, filtering and concentrating sunlight simultaneously and variously onto a photovoltaic cell, a heat collection device, and a thermally activated cooling device for the PV cell in order to efficiently and economically produce electrical power which is simpler in construction, more universally usable and more versatile in operation than known apparatus of this kind.

The purpose of the present invention is to provide a new passive solar collector device that has many novel features not offered by the prior art apparatus that result in a new efficient and economic method of converting sunlight into electricity device which is not apparent, obvious, or suggested, either directly or indirectly by any of the prior art apparatus.

The function of the invention is to passively track the sun for the purposes of collecting, filtering and concentrating sunlight simultaneously and variously onto a photovoltaic cell, a heat collection device, and a thermally activated cooling device for the PV cell in order to efficiently and economically produce electrical power.

### SUMMARY OF THE INVENTION

The present invention generally comprises a holographic light gathering element that also splits the light frequencies and focuses to two or more points or lines. The light frequency is split such that the UV wavelength of interest for PV cell operation is split from all the other wavelengths and focused on the PV cell or light conducting media that will direct the UV to the PV cell location. The other wavelengths of the solar spectrum are focused on a different location that can be simply a “throw-away” of this excess heat or it can be usably focused on a bulb or pipe which collects the heat to be sued for other purposes such as operating an engine or steam turbine or gas/liquid cooling apparatus that could cool the PV solar cell for higher efficiency. The entire system of collector, light directing media, and solar cell/cooler and heat sink device is intended to operate at a concentration of 75 to 250 suns.

Laboratory notes addressing the invention follow.

### BRIEF DESCRIPTION OF THE DRAWINGS

FIG. 1 is of a photonically interconnected power grid, showing the sun and a node of the photonically interconnected power grid;

FIG. 2 is of a basic design as a power transmitter/transponder, showing the sun, white light photons, collecting and converter, electrons 60 Hz, transformer to GRID, and Desert Real Estate;

FIG. 3 is of a self-fund curve of cap equipment budget/kW;

FIG. 4 is of an optical collector array;

FIG. 5 is of a sandwich of glass (or quartz), solgel and substrate;

FIG. 6 is of the Best of the Breed (3×), showing source, (1) holographic lens, (2) solar cell, and (3) cooling method;

FIG. 7 shows sun, lens, heat exchanger, turbine and generator;

FIG. 8 shows cond, val band, and 240 nm-450 nm;

FIG. 9 shows 19%, RT 25° C. and 65° C.;

FIG. 10 shows source, holographic lens, and solar cell, and gaseous cooling method;

FIG. 11 shows source and 64×;

FIG. 12 shows 0.50/ft and banks;

FIG. 13 is of light showers on material, from ⊥ normal incidence to diffuse ∠ on earth, showing shortest path at noon and longer path in morning and evening;

FIG. 14 is of MEMS with edge effects to balance as tracker;

FIG. 15 is of embedded gratings, multiple layers with different settings to be sensitive to angle θ of incidence (could be hologram), showing focus and sources;

FIG. 16 is of collimated white light (ROYGBIV) ∠θ, PV cell (I, V, near UV), and gas cooler (ROYGB) or other;

FIG. 17 is of thin film or plastic for balloons or blimps;

FIG. 18 is of transmissive—passive collectors like Quonset Hut with trough of detector plates down centerline;

FIG. 19 is of fixed stand, passive tracking.

FIG. 20 is of x is larger for θ smaller;

FIG. 21 is of long solid runs with spaces occasionally for service man—or high enough from ground for crawl under;

FIG. 22 is of solar cell farm;

FIG. 23 is of direct 1× absorption collector;

FIG. 24 is of 100× transmission collector;

FIG. 25 is of 100× reflective collector;

FIG. 26 is of muon/pion decay; and

FIG. 27 is of power line near farm.

### DETAILED DESCRIPTION

Latent Dispersive Bragg grating—(hologram) narrow band filter? and/or switch-beam director

can turn on/off with light, sound (vibration), electricity (see electro holograms!) or use as continuous tracking filter c customized beam control (focus) as function of wavelength.

With addition of focus can use as collector/filter c displaced λ dependent focal points.

Inclusion of latency allows a “programmable” hologram in which different elements can be “turned on-off” at will.

Alternatively can have interlaced, fixed (non-latent) holograms (heterodyned?) responsive to incident ∠ of incidence.

| | |
|---|---|
| (84) = 700 | ∫x² = x³/3 |
| 700 = 12e^{84b}ln 700 = ln 12 + 84b $\begin{matrix}\frac{ln 700 - ln ( - 12 )}{84} = b \\ \frac{ln ( 700 / 12 )}{84} = b\end{matrix}$ b = .05 $Σ y = \frac{12 {e}^{( .05 ) x}}{( .05 )}$ | $\begin{matrix}\int y = {\int }_{0}^{84} 12 {e}^{.05 x} \\ = \frac{{{12 {e}^{.05 x} ]}_{0}}^{84}}{( .05 )} \\ = - 240 + 240 {e}^{4.2} \\ = \frac{84 , 672}{12} - 240 \\ = \frac{\$84 , 432 M}{7.036} = \$84 B\end{matrix}$ |
| y(0) = 12y(7) = 700y = Ae^{bx} A = 12700 = 12e^{7b}ln 700 = ln 12 + 7b $\begin{matrix}\frac{ln ( 700 / 12 )}{7} = b \\ \frac{ln ( 58.33 )}{7} = b \\ \frac{4.066}{7} = .58 = b\end{matrix}$ | $\begin{matrix}{\int }_{0}^{7} y = {\int }_{0}^{7} 12 {e}^{.58 x} \\ = \frac{12 ( {e}^{.58 ( x )} - 1 )}{.58} \\ = \frac{12 {e}^{.58 ( x )}}{.58} - \frac{12}{.58} \\ = ( 20.69 ) ( {e}^{4.06} ) - 20.69 \\ = ( 20.69 ) 57.97 - 20.69 \\ = 20.69 [ 56.97 ] \\ = \$1 .178 B \\ \approx \$1 .2 B\end{matrix}$ |
| y₂ = 12e^{.58 · 2} | y₁ = 12e^{.58} |
| y₂ = $38.3 M | y₁ = $21.4 M |

1^{st} 2 yrs = $33.4 M
3 68.4
4 122.1
5 218.1
6 329.5

Solar cell farms—or equiv:

Photonically interconnected power grid
large or small scale—major grid or photocell coupling
   LED—laser/diode transponders

cluster based cost of photocells ?

conversion efficiency ? cost of detectors ? use solar cell?

collect light -> convert to λ or keep broadband ?

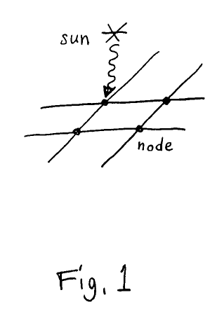

FIG. 1 is of a photonically interconnected power grid, showing the sun * and a node of the photonically interconnected power grid.

Minimize copper wire:

a) node is solar cell -> elec -> led/laser -> collect light -> power photo diode or solar cell -> DC-AC conversion -> put on pwr grid

b) node is hologram/diff grating (mirror)—broadband λ, collect all light -> funnel light to collectors -> collectors are high power photodetectors -> DC-AC conversion -> put on pwr grid

Use basic design as a power transmitter/transponder—get efficiency/insertion loss per element.

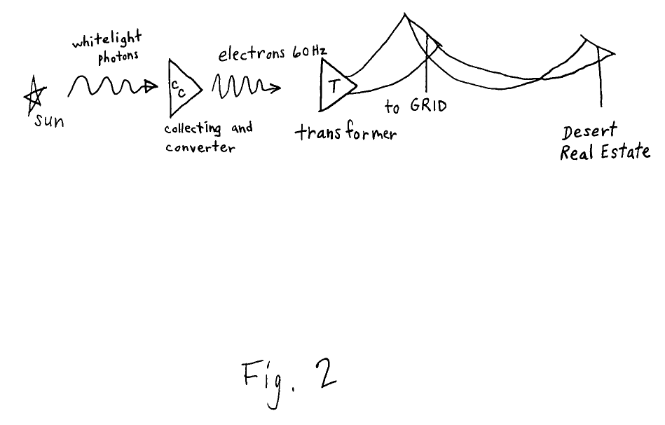

FIG. 2 is of a basic design as a power transmitter/transponder, showing the * sun, white light photons, collecting and converter, electrons 60 Hz, transformer (specs from power company) to GRID, and Desert Real Estate close to GRID/station. Who pays connection cost?

How to collect light in mini cells? How to connect mini-cells? Where to connect λ to e⁻? Compare photoelec effect in metals to semicond! City buy direct? State/Fed funds?

How to collect power cells?

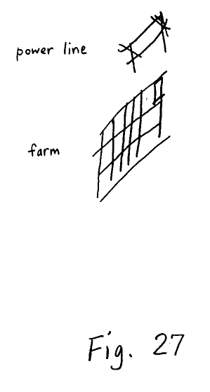

FIG. 27 is of power line near farm.

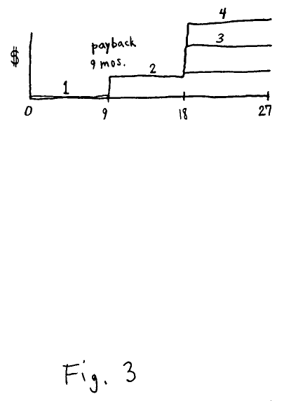

On power end spectrum
1. how much pwr in sunlight—ergs/cm² ?
2. how many times can be multiplied before can't be handled by optics or waveguides ? fn of λ ? Polymer? Lucite? Glass?
3. Hollow core optical waveguides to minimize absorption/dispersion?
4. Highest power diode (photo) on the market? What controls energy density?
5. Loss budget?—insertion losses in control, directing, etc
6. can light be directly converted to AC by having some type of oscillator/cavity/resonance effect embedded monolithically?
7. Cap equipment budget/KW based on current sales price of power to grid? Target 9 mo payback/doubling time? Factor ˜650 in 7/7.5 years—what would self-fund curve look like ?
FIG. 3 is of a self-fund curve of cap equipment budget/kW.
0 mos.: init investment, $100K, 1 cell.
Payback 9 mos.
9 mos.: reinvest, start 2.
18 mos.: have 2 paid to profit from 1. Now add 3 & 4.
27 mos.: cash from 2 & 3 pwr oth 3 & 4. Now add 4 more 5, 6, 7, 8.
1 cell
Say typical electric bill $500/mo/home (3000 kwh @ $0.17/kwh).
Say installation initial $100k -> ˜$11K/mo over 9 mos (equiv 22 homes) ˜$4545 per home -> 66 Megawatt/hr/month.
Budget Installed System per home ($4545⁻)
M 2273 50%
L 909 20%
D 909⁻ 20%
$100K
22 homes
$4545 ea
GPM $454⁻ 10%
assume density 68.75 w/φ.
cash flow per 22 hse unit $11k/mo 1^{st} yr, $7.1M/mo 7^{th} yr.
4×8 sheet
Guess—32 sf of std solar cells—15-20 a AC @ 110 V
P=VI=(110)(20)=2.2 kw
1 house 3000 kw/240 V @ 150 a -> 523φ˜22×22
˜16 panels 4×8
avg hse 1400φ roof
use ½700φ˜1.34 hours of power.
8. Protection? Directional flow? Zeners? Prevent backflow (lightning strikes)?
9. How is best method for “adding” light—inc. amp as fn of λ.
10. Amt of real estate needed? 0.3 to 1 ac (prelim) Lease/buy? Use Row pwr. Co.? 7 yr—say 650 ac.
11. How to handle “no-load” system situation? How to dump power? Capacitors? Control to [symbol]
12. Cost of elements (insertion loss/efficiency?)? How would Ed Baldwin's patent(?) or IP fit into this scenario? Target 1 house grid/element cost to $2273 for 523φ˜36 kw.
13. What happens to “no-load” on a photocell in sunlight—leads open?

FIG. 4 is of an optical collector array.

diffraction grating or hologram lens

4′×8′ 1′×1′ segments
solgel film c hologram ˜50 c ea w/o substrate & cover

4′-6′

64× sun power

solar panel

Alternate, burn hologram into glass c fs laser

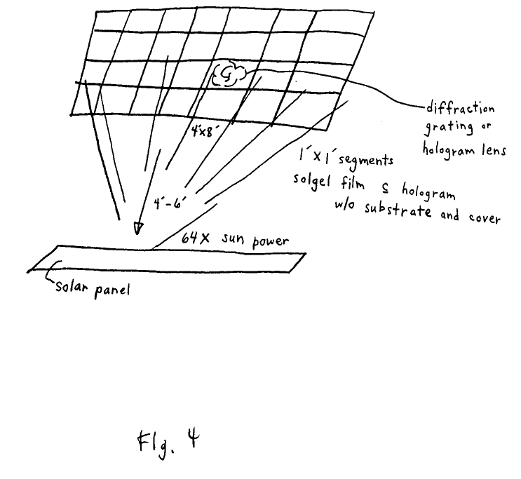

FIG. 5 is of a sandwich of glass (or quartz), solgel and substrate.

use improved glass for UV transm

passive tracking of sun:

use multiplexed holograms, to focus to same point independent of sun angle

Also can filter out unused wavelengths (heat) and just use higher energy, say

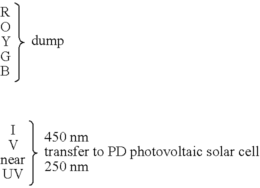

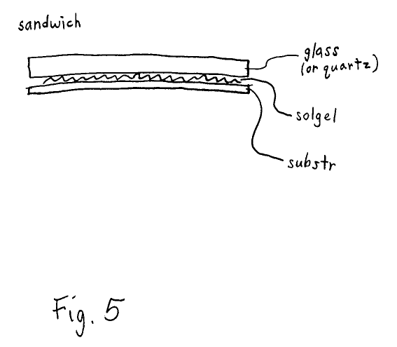

FIG. 6 is of the Best of the Breed (3×), showing source *, (1) holographic lens, (2) solar cell, and (3) cooling method. FIG. 6 shows

| | | | | |
|---|---|---|---|---|
| ROYGB | (1) | holographic lens see db | * | Source |
| | | I, V, near UV 64x | (3) | cooling method see EB |
| | | | (2) | solar cell high power |
| | | | | at 30% instead of 15% |
| | | | | efficiency |
| | | | | see Australia. |

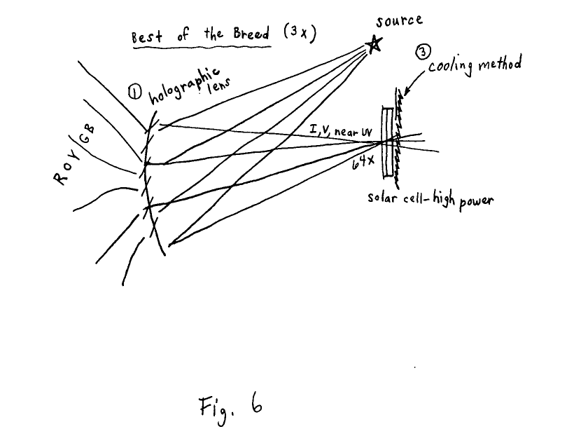

FIG. 7 shows * sun, lens, trough, H.E., turbine and Gen.

Use of Fresnel lens on solar cells?

Can use Holog to increase efficiency of trough system from 1 megawatt to 80 megawatts plus maintenance nightly cleaning problem eliminated. (uses heat to produce steam to drive turbine)

Solar cells e− output ∝ to both λ and intensity but inversely ∝ to temp away from 25° C.

Bandgap?

Absorption curve?

Output as fn of temp?

Why other mtl Than Si for collectors?

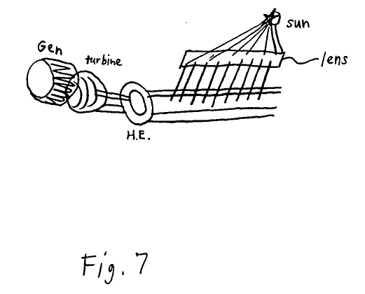

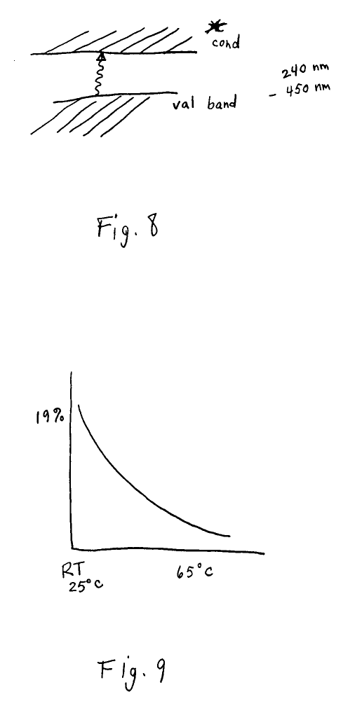

FIG. 8 shows cond, val band, and 240 nm-450 nm.

FIG. 9 shows 19%, RT 25° C. and 65° C.

1. Focus (passive)

2. High eff SC/cheap

3. cooling (filtering)

FIG. 10 shows source *, Holographic lens, and solar cell, and gas cooler. FIG. 10 shows

*

| | |
|---|---|
| H | |
| IR ROYBG | IV near UV |
| | solar cell |
| | gas cooler |
| | talk to John R. |

Cooling

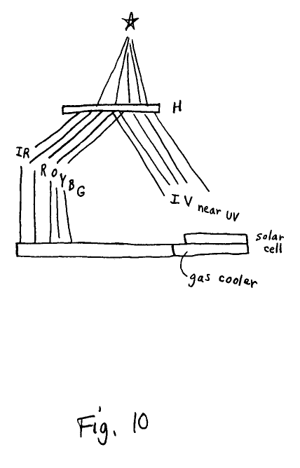

FIG. 11 shows source * and 64×.

FIG. 12 shows 0.50/ft and banks ?

(1) * What does light “see” in its environment at the speed of c in vacuum (ηᵥ)

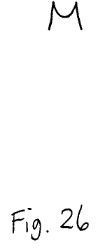

* As it enters & passes thru (or stops) for η>ηᵥ, then does it “see” less/more of the environment. Look at relativity: FIG. 26 is of muon/pion decay narrowing to cone?

(2) Light showers on material: from ⊥ normal incidence to diffuse ∠ on earth does the wavelength distribution change much.

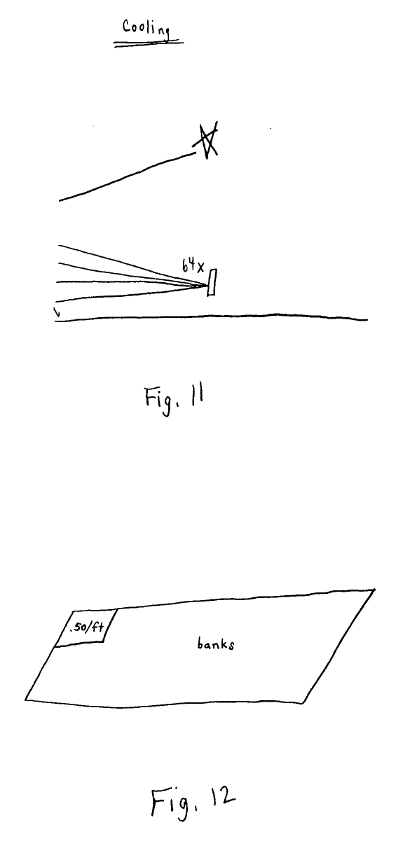

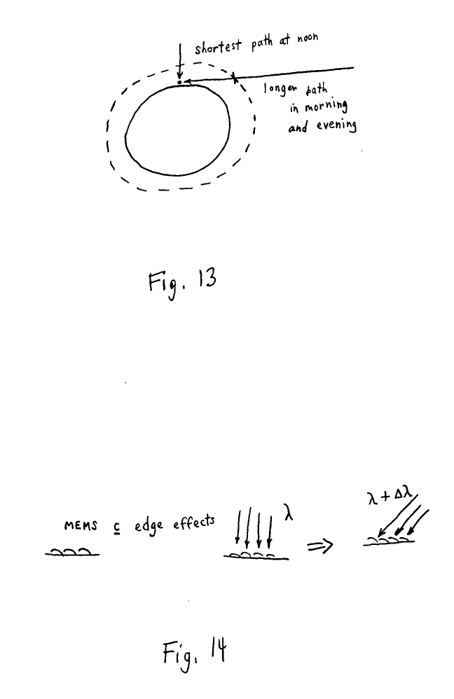

FIG. 13 is of light showers on material, from ⊥ normal incidence to diffuse ∠ on earth, showing shortest path at noon and longer path in morning and evening.

How to actively track?

FIG. 14 is of MEMS c edge effects to balance as tracker.

⊥λ=>λ+Δλ

sensitive to Δλ shift?

(3) How to passively track?

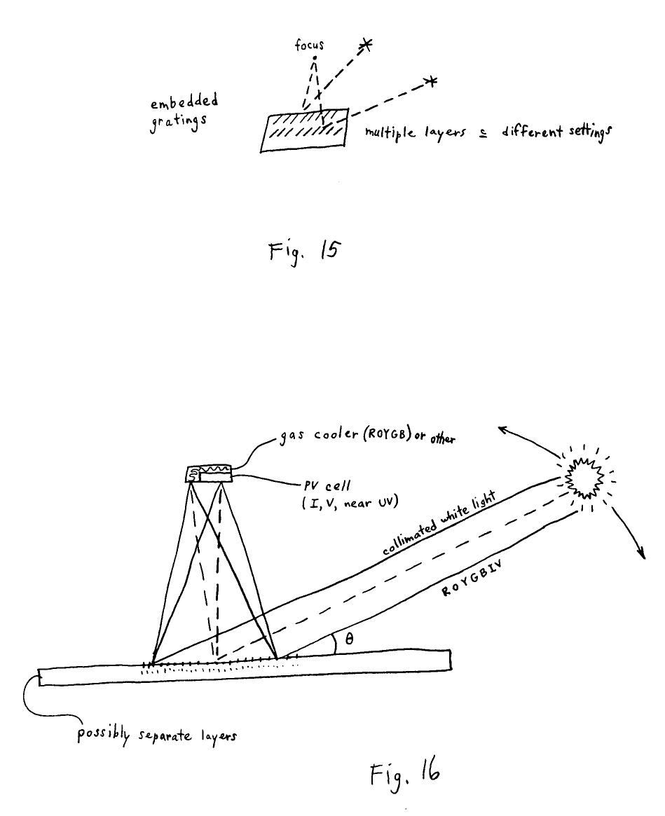

FIG. 15 is of embedded gratings, multiple layers c different settings to be sensitive to angle θ of incidence (could be hologram ?), showing focus and * *.

Can the material (coating or glass, plastic, etc) be a “variable” grating so that some dependence on θ or Δλ of sunlight could turn “off”/“on” diff “layers” c different characteristics? Can one cell be detector/controller for panel? <- pump <- probe

Reverse engineer—light moves along ray paths equally in either direction (if not, have new circulator!)

Reverse design—mathematically (like phase mask) so that foci are sources (not targets)—especially for filtering & refraction/reflection. % efficiency? If cheap, not important.

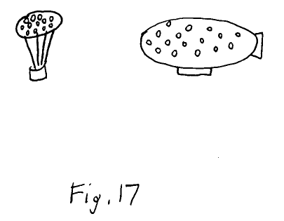

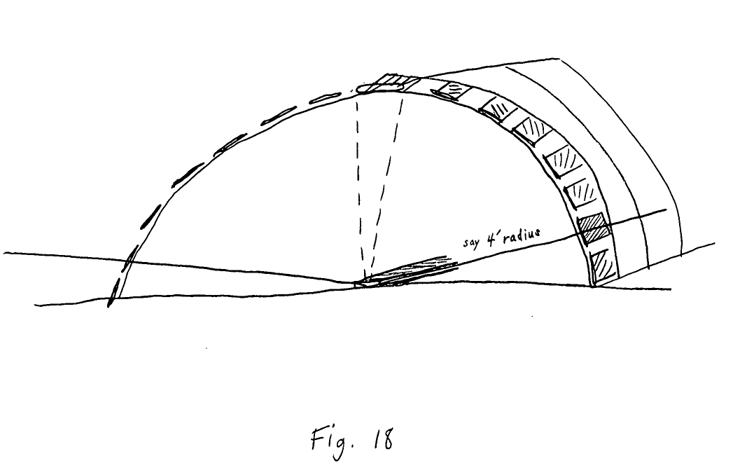

FIG. 16 is of collimated white light ROYGBIV ∠θ, PV cell (I, V, near UV), and gas cooler (ROYGB) or other.

Possibly separate layers combined in ROYGB—“heat” rays to cooler target or for solar water heater I, V, near UV—“purple” rays to PV cell target

What are the θ's? How to keep target from blocking sun? Transmissive?

If it was a hologram, then if shift your eye from one foci to the other, would UV blue/purple at PV and red/orange at cooler.

P.S. Could this be used as

like the old

Solar power vs. weight?

FIG. 17 is of Thin film or plastic for balloons or blimps.

Need energy balance equations!

Make cells like fish scales for roofing & side applications for dual use construction.

Also can use transmissive—passive like Quonset Hut with trough of detector plates down centerline.

FIG. 18 is of transmissive—passive collectors like Quonset Hut with trough of detector plates down centerline.

1′×1′ plate 17″×12″˜144″

If PV cell 1¼×1¼ (˜3 cm×3 cm)=

Ratio 92×

Say 4′ radius

If every 5° out of 180°, 36 plates/lens

“10°” 18 plates/lens

“15°” 12 plates/lens

C=πd=2πr=25.12′

½=12.56′

say 13 plates

180/13=13.85°

At any one time on fn of θ have max ratio of 92 on 1 plate, diminished or no output on other plates, 1 plate 50¢, 12 plates $6.0—cost factor at least 10× on collectors. Spacing problem on land due to shadowing or wall+inc. cost of construction.

Hologram/diff grating can be made as narrow band filter—w/sensitive to θ. So has θ changes (say in increments of 5°), then each succeeding “layer” would turn “on” as the preceding layer turned “off”.

Each “layer” transparent to any angle and any λ except what it's tuned for. How thick the “layer”? How many≡lines in grating/hole pattern?

Sun shading issue.

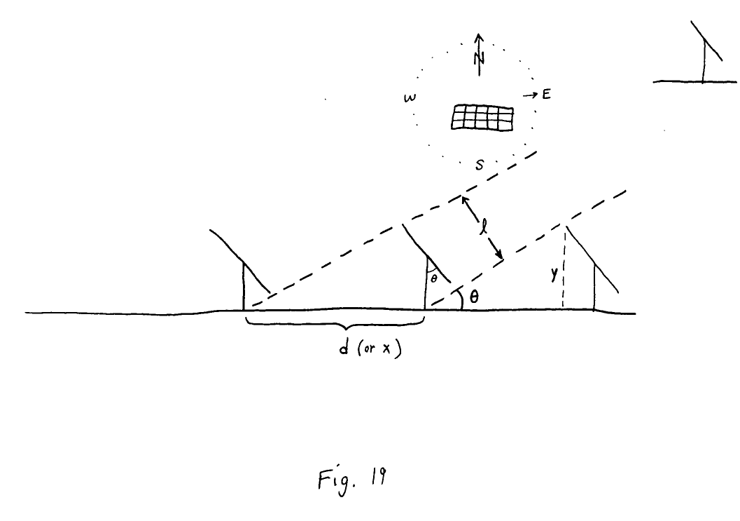

FIG. 19 is of fixed stand, passive tracking.

face south c angle to sun at azimuth. θ=elevation of sun at noon for latitude of installation.

Variables are d, I, and θ or actually the height y: tan θ=y/x, so x=y tan θ. Take case of height y=12′

FIG. 20 is of x is larger for θ smaller.

$$\begin{matrix}θ & tan & x \\ & θ & \\ 35 & .7 & {17.14}^{′} \\ \cdot & & \\ 40 & .84 & {14.28}^{′} \\ \cdot & & \\ 45 & 1 & {12}^{′} \\ \cdot & & \\ 50 & 1.19 & {10}^{′} \\ \cdot & & \\ 55 & 1.43 & {8.4}^{′} \\ \cdot & & \\ 60 & 1.7 & {7.1}^{′} \\ \cdot & & \\ 65 & 2.14 & {5.6}^{′} \\ \cdot & & \\ 70 & 2.75 & {4.4}^{′} \\ \cdot & & \end{matrix}$$

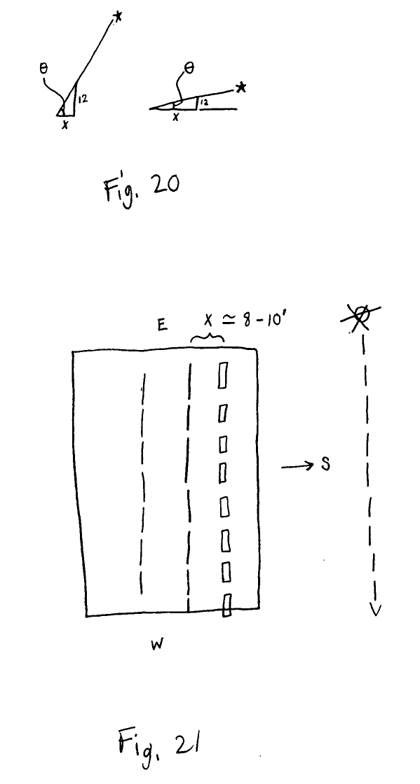

FIG. 21 is of Can be long solid runs with spaces occasionally for service man—or high enough from ground for crawl under. x≅8-10′ perhaps.

FIG. 22 is of solar cell farm.

FIG. 23 is of direct 1× absorption collector.
high cost

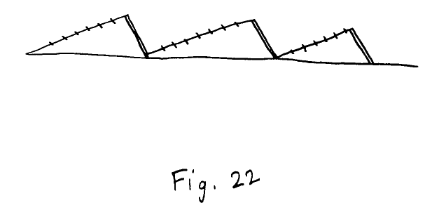

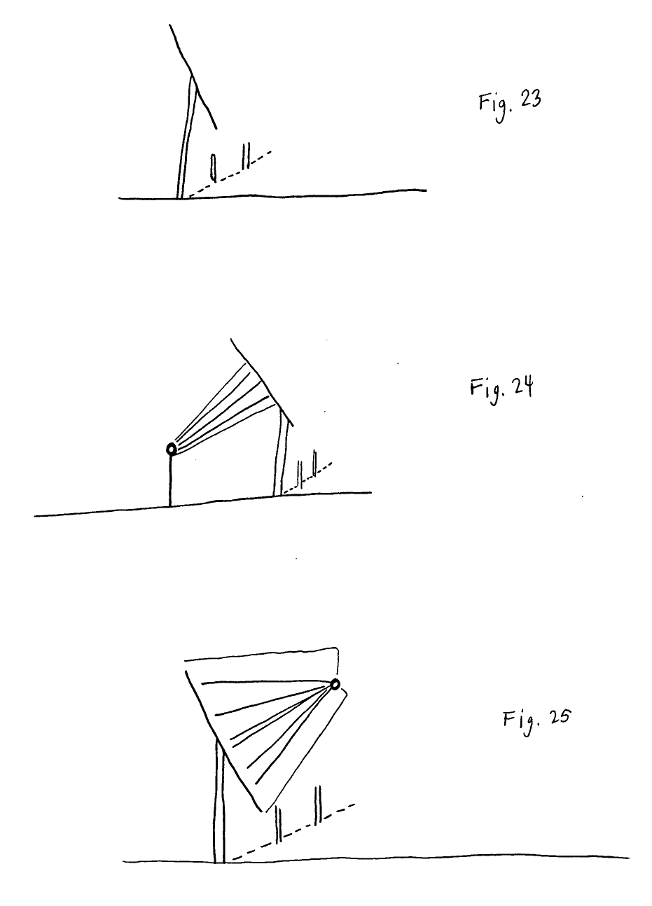

FIG. 24 is of 100× transmission collector.
lose in transmission—absorption
deterioration of material
new tech

FIG. 25 is of 100× reflective collector.
shadowing from detector
new tech
advantage—surface diffraction reflection only

Repeat in the as line (trough) or point (flat or parabolic mount)

Cheapest structural frame? Lifetime? (of cells? Of concentrators? Of frame? Of inverters? 30/20 years min?). Desert—rust may not be problem.

Compare:

1. steel

2. aluminum

3. concrete c rebar/wire

4. plastic

5. fiberglass

6. composite

7. galvanized post's etc.

The foregoing has outlined, in general, the physical aspects of the invention and is to serve as an aid to better understanding the more complete detailed description that is to follow. In reference to such, there is to be a clear understanding that the present invention is not limited to the method or detail of construction, fabrication, material, or application of use described and illustrated herein. Any other variation of fabrication, use, or application should be considered apparent as an alternative embodiment of the present invention.

The invention is to passively track the sun for the purposes of collecting, filtering and concentrating sunlight simultaneously and variously onto a photovoltaic cell, a heat collection device, and a thermally activated cooling device for the PV cell in order to efficiently and economically produce electrical power which is simpler in construction, more universally usable and more versatile in operation than known apparatus of this kind. The present invention generally comprises a holographic light gathering element that also splits the light frequencies and focuses to two or more points or lines. The light frequency is split such that the UV wavelength of interest for PV cell operation is split from all the other wavelengths and focused on the PV cell or light conducting media that will direct the UV to the PV cell location. The other wavelengths of the solar spectrum are focused on a different location that can be simply a “throw-away” of this excess heat or it can be usably focused on a bulb or pipe which collects the heat to be used for other purposes such as operating an engine or steam turbine or gas/liquid cooling apparatus that could cool the PV solar cell for higher efficiency. The entire system of collector, light directing media, solar cell/cooler, and heat sink device is intended to operate at a concentration of 75 to 250 suns.

It is further intended that any other embodiments of the present invention that result from any changes in application or method of use or operation, method of manufacture, shape, size, or material which are not specified within the detained written description or illustrations contained herein yet are considered apparent or obvious to one skilled in the art are within the scope of the present invention.

I claim:

1. A passive tracking solar energy filter, comprising:
a holographic light-gathering element comprising a means for splitting light frequencies into a desired frequency and one or more less desired frequencies;
a heat collector for collecting the desired frequency; and
a solar collector for collecting the one or more less desired frequencies.
